(19) United States
(12) Patent Application Publication
(10) Pub. No.: US 2026/0121685 A1
(43) Pub. Date: Apr. 30, 2026

(54) CIRCUIT FOR IMPLEMENTING CABLE LOCATING AND PAIRING APPLIED TO CABLE MAINTENANCE EQUIPMENT AND CABLE MAINTENANCE EQUIPMENT

(71) Applicant: Yongzhou Noyafa Electronic Co., Ltd., Yongzhou (CN)

(72) Inventors: Ming Lei, Yongzhou (CN); Jianping Zhang, Yongzhou (CN)

(21) Appl. No.: 19/169,016

(22) Filed: Apr. 3, 2025

(30) Foreign Application Priority Data
Oct. 25, 2024 (CN) 202422598618.4

(51) Int. Cl. H04B 3/46; G01R 31/58

(52) U.S. Cl. CPC H04B 3/46; G01R 31/58

(57) ABSTRACT

The present disclosure relates to the technical field of cable locating and pairing. Disclosed are a circuit for implementing cable locating and pairing applied to a cable maintenance equipment and a cable maintenance equipment. The circuit for implementing cable locating and pairing includes a cable locating signal processing circuit and a cable pairing signal transmission circuit. The cable locating signal processing circuit includes a cable locating signal buffer circuit and a cable locating signal transmission circuit. A first terminal of the cable pairing signal transmission circuit is electrically connected to a cable pairing control terminal of the first main control circuit and is configured to be grounded. It is evident that the circuit for implementing cable locating and pairing in the present disclosure is simple in structure and can effectively reduce power consumption of cable locating and pairing.

### CROSS REFERENCE TO RELATED APPLICATIONS

The present disclosure claims the priority of Chinese Patent Application No. 2024225986184 filed on Oct. 25, 2024 before CNIPA. All the above are hereby incorporated by reference in their entirety.

### TECHNICAL FIELD

The present disclosure relates to the technical field of cable pairing and locating, and in particular to a circuit for implementing cable locating and pairing applied to a cable maintenance equipment and a cable maintenance equipment.

### BACKGROUND

Cable maintenance equipment integrated with multiple functions has emerged on the market. When cable maintenance personnel maintain communication cables, this not only reduces the types and quantities of cable maintenance equipment they need to carry, but also allows them to continue using the same cable maintenance equipment to perform other cable maintenance functions after completing a specific one. This significantly enhances the convenience and efficiency for cable maintenance personnel in maintaining communication cables.

Currently, the most common type of multifunctional cable maintenance equipment is cable maintenance equipment integrated with a cable locating function and a cable pairing function, which can switch to a cable pairing mode after completing cable locating, thereby accomplishing cable pairing. This type of cable maintenance equipment typically connects multiple analog switches (e.g., SGM3157) via a micro controller unit (MCU) to transmit cable locating and pairing signals to the cable's interface circuit and performs switching between cable locating and pairing modes, which results in relatively high power consumption when the cable maintenance equipment executes cable locating and pairing functions.

It is evident that how to reduce the power consumption of cable maintenance equipment during the execution of cable locating and pairing functions is a technical problem that needs to be addressed.

### SUMMARY

Provided in the present disclosure is a circuit for implementing cable locating and pairing applied to a cable maintenance equipment and a cable maintenance equipment, which can improve the efficiency and convenience of cable locating and pairing, and at the same time reduce the power consumption of the cable maintenance equipment when performing the function of cable locating and pairing.

Disclosed in a first aspect of the present disclosure is a circuit for implementing cable locating and pairing applied to a cable maintenance equipment, in which the cable maintenance equipment includes at least a host device and a slave device, the host device includes at least a first main control circuit, a first cable interface, and a cable locating and pairing implementation circuit, the cable locating and pairing implementation circuit includes a cable locating signal processing circuit and a cable pairing signal transmission circuit, the cable locating signal processing circuit includes a cable locating signal buffer circuit and a cable locating signal transmission circuit;
a first terminal of the cable pairing signal transmission circuit is electrically connected to a cable pairing control terminal of the first main control circuit, the first terminal of the cable pairing signal transmission circuit is configured to be grounded, a second terminal of the cable pairing signal transmission circuit is electrically connected to a first terminal of the first cable interface;
a first terminal of the cable locating signal buffer circuit is electrically connected to a first cable locating control terminal of the first main control circuit, a second terminal of the cable locating signal buffer circuit is electrically connected to a second cable locating control terminal of the first main control circuit, a third terminal of the cable locating signal buffer circuit is electrically connected to a first terminal of the cable locating signal transmission circuit, a fourth terminal of the cable locating signal buffer circuit is configured to receive a power supply voltage, a fifth terminal of the cable locating signal buffer circuit is configured to be grounded, a second terminal of the cable locating signal transmission circuit is electrically connected to a first terminal of the first cable interface, and a third terminal of the cable locating signal transmission circuit is configured to be grounded.

In a mode of cable locating and pairing of the cable maintenance equipment, a second terminal of the first cable interface is configured to access a terminal of a cable under maintenance, an opposite terminal of the cable under maintenance is configured to access a second cable interface included at the slave device.

As an optional implementation, in a first aspect of the present disclosure, the cable locating signal buffer circuit includes a channel selection driving circuit, a cable locating signal amplification circuit, and a cable locating signal buffer output circuit;
a first terminal of the channel selection driving circuit is electrically connected to a first cable locating control terminal of the first main control circuit; a second terminal of the channel selection driving circuit is electrically connected to an input/output channel selection terminal of the cable locating signal buffer output circuit and configured to receive a power supply voltage; a third terminal of the channel selection driving circuit is configured to be grounded;
a first terminal of the cable locating signal amplification circuit is electrically connected to a second cable locating control terminal of the first main control circuit; a second terminal of the cable locating signal amplification circuit is electrically connected to a signal input terminal of the cable locating signal buffer output circuit; a third terminal of the cable locating signal amplification circuit is configured to be grounded;
a signal output terminal of the cable locating signal buffer output circuit is electrically connected to a first terminal of the cable locating signal transmission circuit.

As an optional implementation, in a first aspect of the present disclosure, the channel selection driving circuit includes a first MOS transistor;
a gate of the first MOS transistor is electrically connected to the first cable locating control terminal of the first main control circuit; a drain of the first MOS transistor is electrically connected to the input/output channel selection terminal of the cable locating signal buffer output circuit (and configured to receive the power supply voltage; a source of the first MOS transistor is configured to be grounded.

As an optional implementation, in a first aspect of the present disclosure, the cable locating signal amplification circuit includes a second MOS transistor;
a gate of the second MOS transistor is electrically connected to the second cable locating control terminal of the first main control circuit; a drain of the second MOS transistor is electrically connected to the signal input terminal of the cable locating signal buffer output circuit and configured to receive the power supply voltage; a source of the second MOS transistor is configured to be grounded.

As an optional implementation, in a first aspect of the present disclosure, the cable locating signal buffer output circuit includes a multi-channel bus buffer;
wherein the multi-channel bus buffer includes at least a plurality of output enable input pins, a plurality of data input pins, a plurality of data output pins, a power supply pin, and a ground pin;
one of the plurality of output enable input pins is configured as the input/output channel selection terminal of the cable locating signal buffer output circuit; one of the plurality of data input pins is configured as the signal input terminal of the cable locating signal buffer output circuit; one of the plurality of data output pins is configured as the signal output terminal of the cable locating signal buffer output circuit.

As an optional implementation, in a first aspect of the present disclosure, the multi-channel bus buffer includes a quad-channel bus buffer, and a model of the quad-channel bus buffer is HC125;
among the output enable input pin configured as the input/output channel selection terminal of the cable locating signal buffer output circuit, the data input pin configured as the signal input terminal of the cable locating signal buffer output circuit, and the data output pin configured as the signal output terminal of the cable locating signal buffer output circuit, there exists an inter-correspondence relationship.

As an optional implementation, in a first aspect of the present disclosure, the host device further includes a cable pairing protection circuit.

A first terminal of the cable pairing signal transmission circuit is electrically connected to both a cable pairing control terminal of the first main control circuit and a first terminal of the cable pairing protection circuit, and a second terminal of the cable pairing protection circuit is configured to be grounded.

As an optional implementation, in a first aspect of the present disclosure, the cable pairing signal transmission circuit includes a plurality of cable pairing signal transmission channels, each of the cable pairing signal transmission channels includes at least a fixed-value resistor and a fuse connected in series; a terminal of the fixed-value resistor is electrically connected respectively to a cable pairing control terminal of the first main control circuit and a first terminal of the cable pairing protection circuit; a terminal of the fuse is electrically connected to a first terminal of the first cable interface;
and/or,
the cable locating signal transmission circuit includes a plurality of first cable locating signal transmission channels and a plurality of second cable locating signal transmission channels, each of the first cable locating signal transmission channels and the second cable locating signal transmission channels includes at least one capacitor; a first terminal of each of the first cable locating signal transmission channels is electrically connected to a third terminal of the cable locating signal buffer circuit, and a second terminal of each of the first cable locating signal transmission channels is electrically connected to a first terminal of the first cable interface; a first terminal of each of the second cable locating signal transmission channels is electrically connected to the first terminal of the first cable interface, and a second terminal of each of the second cable locating signal transmission channels is configured to be grounded.

As an optional implementation, in a first aspect of the present disclosure, the slave device further includes a second main control circuit and a cable locating and pairing signal receiving circuit.

The cable locating and pairing signal receiving circuit includes a plurality of cable locating and pairing signal receiving channels; a first terminal of each of the plurality of cable locating and pairing signal receiving channels is electrically connected to a first terminal of the second cable interface, a second terminal of each of the plurality of cable locating and pairing signal receiving channels is electrically connected to a cable locating and pairing control terminal of the second main control circuit, and a third terminal of each of the plurality of cable locating and pairing signal receiving channels is configured to be grounded.

Disclosed in a second aspect of the present disclosure is a cable maintenance equipment, including at least a host device and a slave device, in which the host device includes at least a first main control circuit and a first cable interface, the host device further includes the cable locating and pairing implementation circuit applied to the cable maintenance equipment according to any one of claims in the present disclosure.

Compared to the prior art, the embodiments of the present disclosure have beneficial effects as follows.

According to the present disclosure, the circuit for implementing cable locating and pairing applied to a cable maintenance equipment includes a cable locating signal processing circuit and a cable pairing signal transmission circuit. A first terminal of the cable pairing signal transmission circuit is electrically connected to a cable pairing control terminal of the first main control circuit in a host device of the cable maintenance equipment, the first terminal of the cable pairing signal transmission circuit is configured to be grounded, a second terminal of the cable pairing signal transmission circuit is electrically connected to a first terminal of the first cable interface in the host device; a first terminal of the cable locating signal buffer circuit is electrically connected to a first cable locating control terminal of the first main control circuit, a second terminal of the cable locating signal buffer circuit is electrically connected to a second cable locating control terminal of the first main control circuit, a third terminal of the cable locating signal buffer circuit is electrically connected to a first terminal of the cable locating signal transmission circuit, a fourth terminal of the cable locating signal buffer circuit is configured to receive a power supply voltage, a fifth terminal of the cable locating signal buffer circuit is configured to be grounded, a second terminal of the cable locating signal transmission circuit is electrically connected to a first terminal of the first cable interface, and a third terminal of the cable locating signal transmission circuit is configured to be grounded. In the mode of cable locating and pairing of the cable maintenance equipment, the second terminal of the first cable interface is configured to access a terminal of a cable under maintenance, and an opposite terminal of the cable under maintenance is configured to access a second cable interface in the slave device of the cable maintenance equipment. It is evident that the circuit for implementing cable locating and pairing in the present disclosure is simple in structure and can effectively reduce power consumption of cable locating and pairing. Furthermore, the cable locating signal and the cable pairing signal are designed with isolated grounding paths, which effectively reduces or avoids common ground interference between the cable locating and pairing signals.

### BRIEF DESCRIPTION OF THE DRAWINGS

In order to illustrate the technical solutions of the embodiments of the present disclosure more clearly, the following drawings are briefly described as required in the context of the embodiments. Obviously, the following drawings illustrate only some of the embodiments of the present disclosure. Other relevant drawings may be obtained on the basis of these drawings without any creative effort by those skilled in the art.

FIG. 1 is a schematic structural diagram of a circuit for implementing cable locating and pairing applied to a cable maintenance equipment disclosed in an embodiment of the present disclosure;

FIG. 2 is a schematic structural diagram of another circuit for implementing cable locating and pairing applied to a cable maintenance equipment disclosed in the embodiment of the present disclosure;

FIG. 3 is a schematic structural diagram of the first main control circuit in a host device disclosed in the embodiment of the present disclosure;

FIG. 4 is a schematic structural diagram of the cable pairing protection circuit in the host device disclosed in the embodiment of the present disclosure;

FIG. 5 is a schematic structural diagram of a slave device disclosed in the embodiment of the present disclosure;

FIG. 6 is a schematic structural diagram of the second main control circuit in the slave device disclosed in the embodiment of the present disclosure; and

FIG. 7 is a schematic structural diagram of the cable locating and pairing signal receiving circuit in the slave device disclosed in the embodiment of the present disclosure.

### DETAILED DESCRIPTION

For a better understanding of the solutions of the present disclosure by those skilled in the art, the technical solutions in the embodiments of the present disclosure are clearly and completely described and discussed below in conjunction with the attached drawings of the embodiments of the present disclosure. Obviously, the embodiments described herein are only some of the embodiments of the present disclosure but not all of them. Based on the embodiments in the present disclosure, all other embodiments acquired by those skilled in the art without inventive effort fall within the scope of protection of the present disclosure.

The terms “first”, “second”, and the like in the specification, the claims and the above-mentioned drawings of the present disclosure are used to identify different objects and are not intended to describe a particular sequence. In addition, the terms “comprise” and “include”, and any derivatives and conjugations thereof, are intended to cover non-exclusive inclusion. For example, a process, method, apparatus, product, or device that includes a series of steps or units is not limited to the listed steps or units, but optionally also includes steps or units that are not listed, or optionally also includes other steps or units that are inherent to those processes, methods, products, or devices.

The term “embodiment” herein means that a particular feature, structure or characteristic described in conjunction with an embodiment may be included in at least one embodiment of the present disclosure. The presence of the term in various places in the specification does not necessarily indicate the same embodiment, nor is it a separate or alternative embodiment that is mutually exclusive with other embodiments. It is understood, both explicitly and implicitly, by those skilled in the art that the embodiments described herein may be combined with other embodiments.

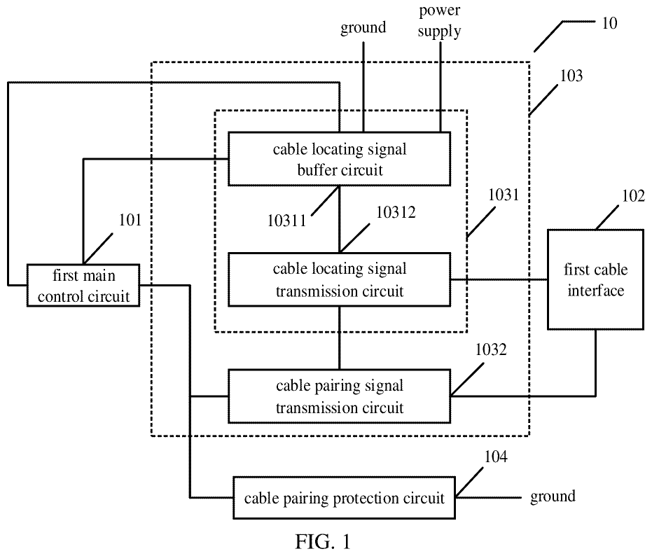

Disclosed in the present disclosure is a circuit for implementing cable locating and pairing applied to a cable maintenance equipment and a cable maintenance equipment, which implements the function of cable locating and pairing through a simple cable locating and pairing implementation circuit, and effectively reduces the power consumption of cable locating and pairing. Furthermore, the cable locating signal and the cable pairing signal are designed with isolated grounding paths, which effectively reduces or avoids common ground interference between the cable locating and pairing signals. The following are detailed descriptions of the cable locating and pairing implementation circuit, the host device of the cable maintenance equipment, and the slave device of the cable maintenance equipment involved in the present disclosure in conjunction with FIGS. 1-7, respectively.

### Embodiment 1

Referring to FIG. 1, FIG. 1 is a schematic structural diagram of a circuit for implementing cable locating and pairing applied to a cable maintenance equipment disclosed in an embodiment of the present disclosure. The cable maintenance equipment includes at least a host device 10 and a slave device 20. The host device 10 includes at least a first main control circuit 101, a first cable interface 102, and a cable locating and pairing implementation circuit 103. Further, as shown in FIG. 1, the cable locating and pairing implementation circuit 103 includes a cable locating signal processing circuit 1031 and a cable pairing signal transmission circuit 1032. The cable locating signal processing circuit 1031 may include a cable locating signal buffer circuit 10311 and a cable locating signal transmission circuit 10312. A first terminal of the cable pairing signal transmission circuit 1032 is electrically connected to a cable pairing control terminal of the first main control circuit 101, the first terminal of the cable pairing signal transmission circuit 1032 is configured to be grounded, and a second terminal of the cable pairing signal transmission circuit 1032 is electrically connected to a first terminal of the first cable interface 102.

A first terminal of the cable locating signal buffer circuit 10311 is electrically connected to a first cable locating control terminal of the first main control circuit 101, a second terminal of the cable locating signal buffer circuit 10311 is electrically connected to a second cable locating control terminal of the first main control circuit 101, a third terminal of the cable locating signal buffer circuit 10311 is electrically connected to a first terminal of the cable locating signal transmission circuit 10312, a fourth terminal of the cable locating signal buffer circuit 10311 is configured to receive a power supply voltage, a fifth terminal of the cable locating signal buffer circuit 10311 is configured to be grounded, a second terminal of the cable locating signal transmission circuit 10312 is electrically connected to a first terminal of the first cable interface 102, and a third terminal of the cable locating signal transmission circuit 10312 is configured to be grounded.

In a mode of cable locating and pairing of the cable maintenance equipment, a second terminal of the first cable interface 102 is configured to access a terminal of a cable under maintenance, an opposite terminal of the cable under maintenance is configured to access a second cable interface 201 included at the slave device 20.

It is evident that the cable locating and pairing implementation circuit 103 described by the embodiment of the present disclosure is simple in structure with low costs and can effectively reduce the power consumption of cable locating and pairing. Furthermore, the cable locating signal processing circuit 1031 and the cable pairing signal transmission circuit 1032 are designed with isolated grounding paths, i.e., the cable locating signal and the cable pairing signal being designed with isolated grounding paths, which may effectively reduce or avoid common ground interference between the cable locating and pairing signals.

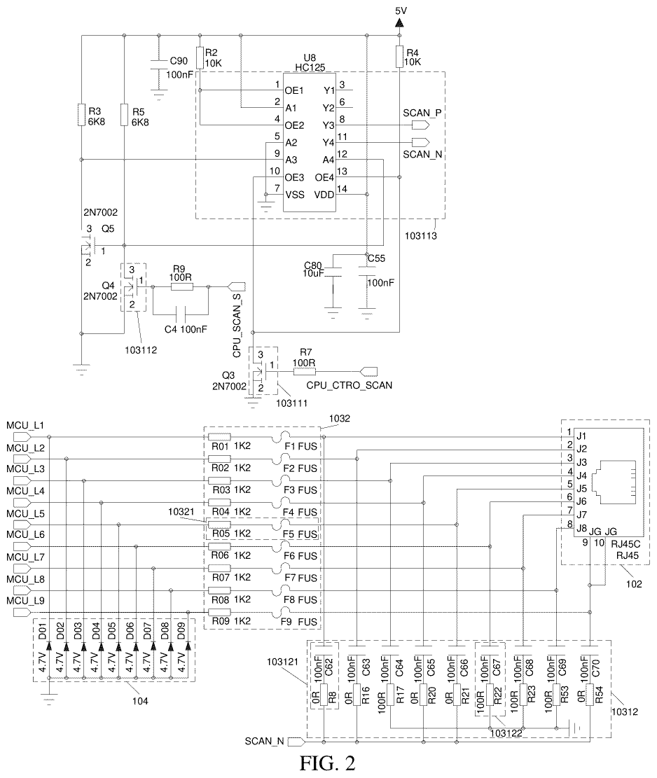

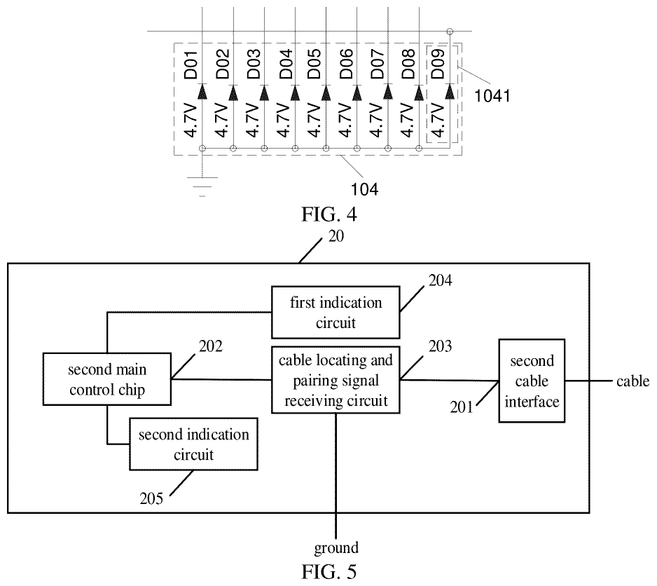

In an optional implementation, as shown in FIG. 1, the host device 10 further includes a cable pairing protection circuit 104. A first terminal of the cable pairing signal transmission circuit 1032 is electrically connected to both a cable pairing control terminal of the first main control circuit 101 and a first terminal of the cable pairing protection circuit 104, and a second terminal of the cable pairing protection circuit 104 is configured to be grounded. Further and optionally, referring to FIG. 4 for the detailed circuit structure of the cable pairing protection circuit 104, FIG. 4 is a schematic structural diagram of the cable pairing protection circuit in the host device disclosed in the embodiment of the present disclosure. As shown in FIG. 4, the cable pairing protection circuit 104 may include multiple cable pairing protection sub-circuits 1041. As further illustrated in FIG. 2, the cable pairing signal transmission circuit 1032 may include a plurality of cable pairing signal transmission channels 10321. In some implementations, each cable pairing signal transmission channel 10321 corresponds to one cable pairing protection sub-circuit 1041.

Further and optionally, the cable pairing protection sub-circuits 1041 included in the cable pairing protection circuit 104 may specifically be the diodes D01 to D09 shown in FIG. 4. An anode of each diode is grounded; a cathode of each diode serves as a first terminal of the cable pairing protection circuit 104 and is electrically connected to a first terminal of the cable pairing signal transmission circuit 1032. It is evident that, according to this optional embodiment, the cable pairing protection circuit 104 effectively reduces the risk of burnout in the first main control circuit 101 caused by connecting a cable under maintenance to the host device 10, thereby enhancing the operational safety of the cable locating and pairing implementation circuit 103.

In another optional implementation, as shown in FIG. 2, the cable locating signal buffer circuit 10311 includes a channel selection driving circuit 103111, a cable locating signal amplification circuit 103112, and a cable locating signal buffer output circuit 103113.

A first terminal of the channel selection driving circuit 103111 is electrically connected to a first cable locating control terminal of the first main control circuit 101; a second terminal of the channel selection driving circuit 103111 is electrically connected to an input/output channel selection terminal of the cable locating signal buffer output circuit 103113 and configured to receive a power supply voltage; and a third terminal of the channel selection driving circuit 103111 is configured to be grounded.

A first terminal of the cable locating signal amplification circuit 103112 is electrically connected to a second cable locating control terminal of the first main control circuit 101; a second terminal of the cable locating signal amplification circuit 103112 is electrically connected to a signal input terminal of the cable locating signal buffer output circuit 103113; and a third terminal of the cable locating signal amplification circuit 103112 is configured to be grounded.

A signal output terminal of the cable locating signal buffer output circuit 103113 is electrically connected to a first terminal of the cable locating signal transmission circuit 10312.

In this optional implementation, further and optionally, as shown in FIG. 2, the aforementioned channel selection driving circuit 103111 includes a first MOS transistor Q3.

A gate of the first MOS transistor Q3 is electrically connected to the first cable locating control terminal CPU_CTRO_SCAN of the first main control circuit 101; a drain of the first MOS transistor Q3 is electrically connected to the input/output channel selection terminal of the cable locating signal buffer output circuit 103113 and configured to receive the power supply voltage; a source of the first MOS transistor Q3 is configured to be grounded.

In this optional implementation, further and optionally, as shown in FIG. 2, the cable locating signal amplification circuit 103112 includes a second MOS transistor Q4.

A gate of the second MOS transistor Q4 is electrically connected to the second cable locating control terminal CPU_SCAN_S of the first main control circuit 101; a drain of the second MOS transistor Q4 is electrically connected to the signal input terminal of the cable locating signal buffer output circuit 103113 and configured to receive the power supply voltage; a source of second MOS transistor Q4 is configured to be grounded.

It is evident that, this optional implementation enables channel selection and signal amplification to be respectively implemented via MOS transistors, achieving a simple structure with low costs.

In this optional implementation, further and optionally, as shown in FIG. 2, the cable locating signal buffer output circuit 103113 includes a multi-channel bus buffer.

The multi-channel bus buffer includes at least a plurality of output enable input pins, a plurality of data input pins, a plurality of data output pins, a power supply pin, and a ground pin.

One of the plurality of output enable input pins is configured as the input/output channel selection terminal of the cable locating signal buffer output circuit 103113; one of the plurality of data input pins is configured as the signal input terminal of the cable locating signal buffer output circuit 103113; one of the plurality of data output pins is configured as the signal output terminal of the cable locating signal buffer output circuit 103113.

In this optional implementation, further and optionally, as shown in FIG. 2, the multi-channel bus buffer includes a quad-channel bus buffer, and a model of the quad-channel bus buffer is HC125.

Among the output enable input pin configured as the input/output channel selection terminal of the cable locating signal buffer output circuit 103113, the data input pin configured as the signal input terminal of the cable locating signal buffer output circuit 103113, and the data output pin configured as the signal output terminal of the cable locating signal buffer output circuit 103113, there exists an inter-correspondence relationship. Taking the quad-channel bus buffer in FIG. 2 as an example: the output enable input pins of the quad-channel bus buffer are OE1 to OE4 respectively; the data input pins of the quad-channel bus buffer are A1 to A4 respectively; the data output pins of the quad-channel bus buffer are Y1 to Y4 respectively; and each output enable input pin (OEn) corresponds to one data input pin (An) and one data output pin (Yn). The output enable input pin configured as the input/output channel selection terminal of the cable locating signal buffer output circuit 103113 is named as OE4, the signal input terminal of the cable locating signal buffer output circuit 103113 is the pin A4, and the signal output terminal of the cable locating signal buffer output circuit 103113 is the pin Y4. That is, the logic level of the output enable input pin at OE4 controls the output state of the buffer channel corresponding to the pin A4, the pin A4 serves as the input pin of the corresponding buffer channel, and the pin Y4 serves as the output pin of the corresponding buffer channel.

It is evident that this optional implementation enables the functions of signal buffering and signal output of the cable locating signal buffer output circuit 103113 implemented via the multi-channel bus buffer and also features a simple structure.

In this optional implementation, further and optionally, as shown in FIG. 2, the cable pairing signal transmission circuit 1032 comprises a plurality of cable pairing signal transmission channels 10321, each of the cable pairing signal transmission channels 10321 includes at least a fixed-value resistor (R01 to R09 as shown in FIG. 2) and a fuse (F1 to F9 as shown in FIG. 2) connected in series; a terminal of the fixed-value resistor is electrically connected respectively to a cable pairing control terminal (i.e., MCU_L1 to MCU_L9) of the first main control circuit 101 and a first terminal of the cable pairing protection circuit 104; a terminal of the fuse is electrically connected to a first terminal of the first cable interface 102.

In this optional implementation, further and optionally, as shown in FIG. 2, the cable locating signal transmission circuit 10312 includes a plurality of first cable locating signal transmission channels 103121 and a plurality of second cable locating signal transmission channels 103122. Each of the first cable locating signal transmission channels 103121 and the second cable locating signal transmission channels 103122 includes at least one capacitor, and may further include a resistor connected with the capacitor in series. A first terminal (a terminal of R8, R16, R20, R21, and R54 as shown in FIG. 2) of each of the first cable locating signal transmission channels 103121 is electrically connected to a third terminal of the cable locating signal buffer circuit 10311. A second terminal (a terminal of C62, C63, C65, C66, and C70 as shown in FIG. 2) of each of the first cable locating signal transmission channels 103121 is electrically connected to a first terminal of the first cable interface 102. A first terminal (a terminal of C64, C67, C68, and C69 as shown in FIG. 2) of each of the second cable locating signal transmission channels 103122 is electrically connected to the first terminal of the first cable interface 102. A second terminal (a terminal of R17, R22, R23, and R53 as shown in FIG. 2) of each of the second cable locating signal transmission channels 103122 is configured to be grounded.

It is evident that the optional embodiment also enables the function of cable pairing and cable locating via fuses, resistors, and capacitors, respectively, which is simple and low-cost to implement.

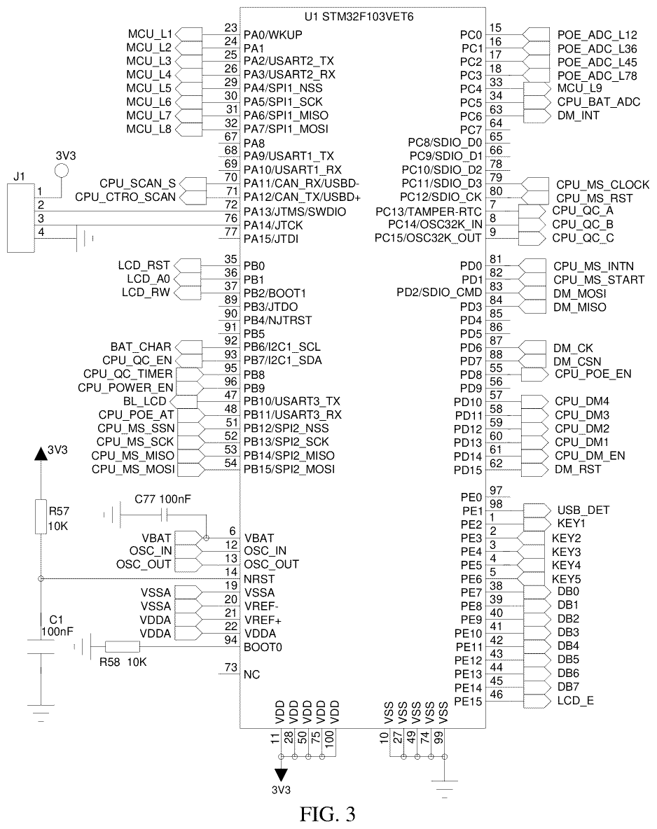

In yet another optional implementation, referring to FIG. 3 for the structure of the first main control circuit 101 of the aforementioned host device 10, FIG. 3 is a schematic structural diagram of the first main control circuit in a host device disclosed in the embodiment of the present disclosure. As shown in FIG. 3, the first main control circuit may include a main control chip U1 of model STM32F103VET6.

In yet another optional embodiment, the structure of the aforementioned slave device 20 may be referred to FIG. 5, and FIG. 5 is a schematic structural diagram of a slave device disclosed in the embodiment of the present disclosure. As shown in FIG. 5, the slave device 20 includes, in addition to a second cable interface 201, a second main control circuit 202 and a cable locating and pairing signal receiving circuit 203.

Further, as shown in FIG. 5, the slave device 20 may further include a first indication circuit 204 and/or a second indication circuit 205. The first indication circuit 204 is configured to output cable pairing sequence results, and the second indication circuit (205) is configured to output correlated results of cable sequence faults and received signal strength.

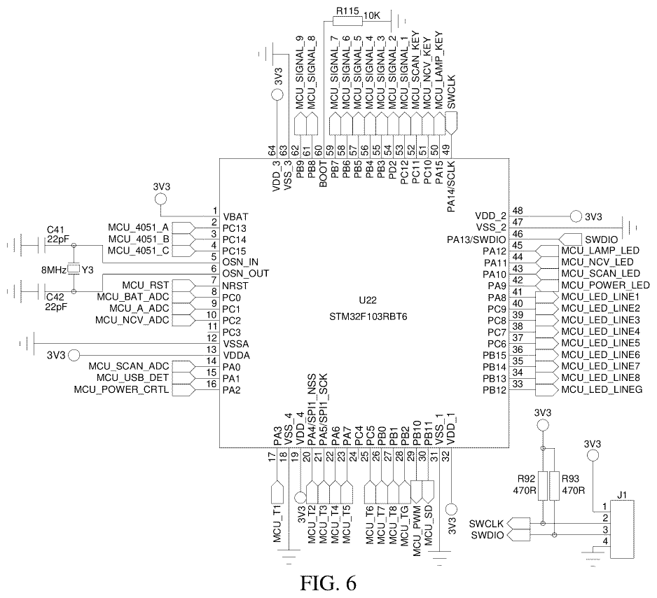

In this optional implementation, further, referring to FIG. 6 for the structure of the second main control circuit 202 of the slave device 20, FIG. 6 is a schematic structural diagram of the second main control circuit in the slave device disclosed in the embodiment of the present disclosure. As shown in FIG. 6, the second main control circuit 202 may include a main control chip U22 of model STM32F103RBT6.

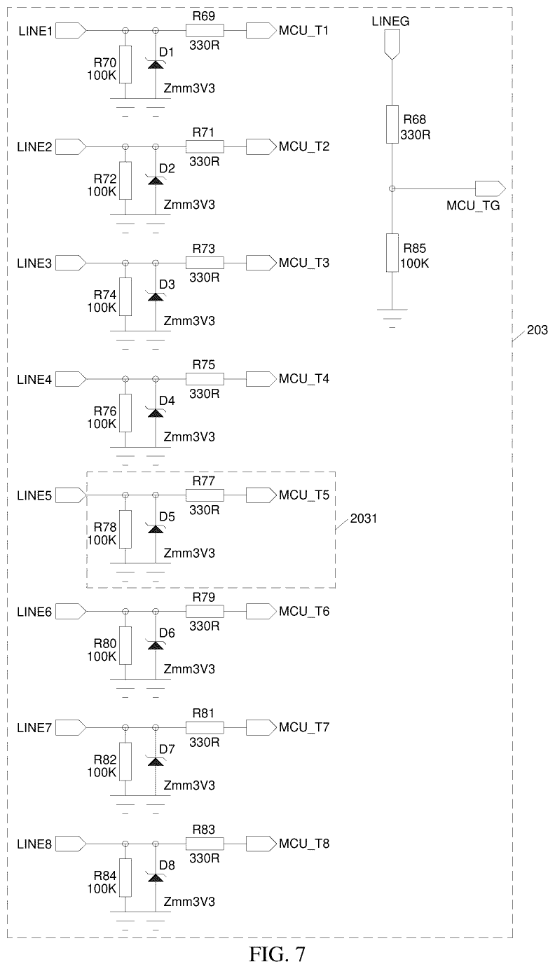

In this optional implementation, further, referring to FIG. 7 for the structure of the cable locating and pairing signal receiving circuit 203 of the slave device 20, FIG. 7 is a schematic structural diagram of the cable locating and pairing signal receiving circuit in the slave device disclosed in the embodiment of the present disclosure. As shown in FIG. 7, the cable locating and pairing signal receiving circuit 203 includes a plurality of cable locating and pairing signal receiving channels 2031; a first terminal (LINE 1 to LINE 8 as shown in FIG. 7) of each of the plurality of cable locating and pairing signal receiving channels 2031 is electrically connected to a first terminal of the second cable interface 201, a second terminal of each of the plurality of cable locating and pairing signal receiving channels 2031 is electrically connected to a cable locating and pairing control terminal (MCU_T1 to MCU_T8 as shown in FIG. 7) of the second main control circuit 202, and a third terminal of each of the plurality of cable locating and pairing signal receiving channels 2031 is configured to be grounded.

Further, each of the plurality of cable locating and pairing signal receiving channels 2031 may respectively include a first resistor (R70, R72, R74, R76, R78, R80, R82, and R84 as shown in FIG. 7) and a Zener diode (D1, D2, D3, D4, D6, D7, D8, and D9 as shown in FIG. 7) connected in parallel, and may further include a second resistor (R69, R71, R73, R75, R77, R79, R81, and R83 as shown in FIG. 7) electrically connected to a cathode of the Zener diode. The cathode of the Zener diode serves as the first terminal of the cable locating and pairing signal receiving channel 2031, while the anode of the Zener diode serves as the third terminal of the cable locating and pairing signal receiving channel 2031. The other terminal of the second resistor electrically connected to the cathode of the Zener diode serves as the second terminal of the cable locating and pairing signal receiving channel 2031.

It is evident that this optional embodiment further enables cable pairing functionality expansion on the slave device 20 through a simplified circuit structure, achieving both structural simplicity and high safety. Additionally, it allows cable maintenance personnel to directly obtain on the slave device 20: cable pairing results, related fault information, signal strength information, thereby enhancing the efficiency and convenience of cable maintenance personnel in obtaining pairing results, related fault information, signal strength information, and thus contributing to the improvement of the efficiency and convenience of cable maintenance.

### Embodiment 2

Disclosed in the present embodiment of the disclosure is a cable maintenance equipment. The cable maintenance equipment includes at least a host device 10 and a slave device 20. The host device 10 includes at least a first main control circuit 101 and a first cable interface 102, and the host device 10 further includes any one of the cable locating and pairing implementation circuit 103 described in Embodiment 1. Furthermore, other descriptions for the host device 10 and the slave device 20 may refer specifically to the relevant descriptions in Embodiment 1, which are not repeated in the present embodiment of the disclosure. It is evident that the cable maintenance equipment in the embodiment of the present disclosure not only integrates the function of cable locating and pairing, but also features a simplified circuit architecture for implementing the function of cable locating and pairing, which can effectively reduce power consumption of cable locating and pairing. Furthermore, the cable locating signal and the cable pairing signal are designed with isolated grounding paths, which effectively reduces or avoids common ground interference between the cable locating and pairing signals.

Further, the cable locating and pairing implementation principle of the cable maintenance device disclosed in the present disclosure operates as follows: in the cable locating mode, the main control chip U1 of the host device 10 transmits a cable locating signal (e.g., a PWM signal) to the gate of the second MOS transistor Q4. The cable locating signal is amplified by the second MOS transistor Q4 and then routed through the quad-channel bus buffer U8 to the cable locating signal transmission circuit 10312. Specifically, the signal is transmitted to lines LINE1, 2, 4, 5, and 9 of the cable locating signal transmission circuit 10312, while lines LINE3, 6, 7, and 8 are grounded.

The cable locating signal processing circuit 1031, upon receiving a cable locating signal, beeps to notify the user. The other terminal of the cable is terminated at the second cable interface 201 of the slave device 20. After the host device 10 successfully receives a handshake signal from the slave device 20, it automatically switches to cable pairing mode.

In cable pairing mode, the main control chip U1 of the host device 10 directly transmits cable pairing signals to the cable pairing signal transmission circuit 1032. More specifically, the main control chip U1 sends cable pairing signals to the cable pairing signal transmission circuit 1032 using a sequential LED activation pattern.

Simultaneously, the slave device 20 receives the cable pairing signals via the cable. The first indication circuit 204 of the slave device 20 synchronizes its LED sequence illumination with the host device's cable order indicator lights in a progressive manner, to detect potential cable abnormalities.

It is necessary to further specify that: in addition to including the functional circuits mentioned in the present disclosure, the cable maintenance equipment may also include other functional circuits, such as power supply circuits, power state indication circuits, key circuits, mode selection circuits, length measurement circuits, and so on, which are not limited by the present disclosure.

The aforementioned described embodiments of the cable maintenance equipment and other relevant circuit structure are only illustrative. The electric components described as separate components may or may not be physically separated, and the modules used as components for display may or may not be physical modules, that is, they may be located in the same place or may be distributed to a plurality of network modules. Some or all these modules may be selected according to practical demands to achieve the purpose of the solution of the present embodiment. It may be understood and performed by a person of ordinary skill in the art without inventive effort.

Finally, it should be noted that the circuit for implementing cable locating and pairing applied to a cable maintenance equipment and the cable maintenance equipment disclosed in the embodiments of the present disclosure are only preferred embodiments of the present disclosure, and are only used to illustrate the technical solutions of the present disclosure, but not to limit them. Despite the detailed description of the disclosure with reference to the aforementioned embodiments, it should be understood, by those skilled in the art, that the technical solutions recorded in the aforementioned embodiments may still be modified, or equivalent substitutions for some of the technical features thereof may be made; which the essence of the corresponding technical solutions of these modifications or substitutions is without departing from the spirit and scope of the technical solutions of the various embodiments of the disclosure.

1. A circuit for implementing cable locating and pairing applied to a cable maintenance equipment, wherein the cable maintenance equipment comprises at least a host device and a slave device, the host device comprises at least a first main control circuit, a first cable interface, and a cable locating and pairing implementation circuit, the cable locating and pairing implementation circuit comprises a cable locating signal processing circuit and a cable pairing signal transmission circuit, the cable locating signal processing circuit comprises a cable locating signal buffer circuit and a cable locating signal transmission circuit;
a first terminal of the cable pairing signal transmission circuit is electrically connected to a cable pairing control terminal of the first main control circuit, the first terminal of the cable pairing signal transmission circuit is configured to be grounded, a second terminal of the cable pairing signal transmission circuit is electrically connected to a first terminal of the first cable interface;
a first terminal of the cable locating signal buffer circuit is electrically connected to a first cable locating control terminal of the first main control circuit, a second terminal of the cable locating signal buffer circuit is electrically connected to a second cable locating control terminal of the first main control circuit, a third terminal of the cable locating signal buffer circuit is electrically connected to a first terminal of the cable locating signal transmission circuit, a fourth terminal of the cable locating signal buffer circuit is configured to receive a power supply voltage, a fifth terminal of the cable locating signal buffer circuit is configured to be grounded, a second terminal of the cable locating signal transmission circuit is electrically connected to a first terminal of the first cable interface, and a third terminal of the cable locating signal transmission circuit is configured to be grounded.

2. The circuit for implementing cable locating and pairing applied to the cable maintenance equipment according to claim 1, wherein the cable locating signal buffer circuit comprises a channel selection driving circuit, a cable locating signal amplification circuit, and a cable locating signal buffer output circuit;
wherein a first terminal of the channel selection driving circuit is electrically connected to a first cable locating control terminal of the first main control circuit; a second terminal of the channel selection driving circuit is electrically connected to an input/output channel selection terminal of the cable locating signal buffer output circuit and configured to receive a power supply voltage; a third terminal of the channel selection driving circuit is configured to be grounded;
a first terminal of the cable locating signal amplification circuit is electrically connected to a second cable locating control terminal of the first main control circuit; a second terminal of the cable locating signal amplification circuit is electrically connected to a signal input terminal of the cable locating signal buffer output circuit; a third terminal of the cable locating signal amplification circuit is configured to be grounded;
a signal output terminal of the cable locating signal buffer output circuit is electrically connected to a first terminal of the cable locating signal transmission circuit.

3. The circuit for implementing cable locating and pairing applied to the cable maintenance equipment according to claim 2, wherein the channel selection driving circuit comprises a first MOS transistor;
wherein a gate of the first MOS transistor is electrically connected to the first cable locating control terminal of the first main control circuit; a drain of the first MOS transistor is electrically connected to the input/output channel selection terminal of the cable locating signal buffer output circuit and configured to receive the power supply voltage; a source of the first MOS transistor is configured to be grounded.

4. The circuit for implementing cable locating and pairing applied to the cable maintenance equipment according to claim 2, wherein the cable locating signal amplification circuit comprises a second MOS transistor;
wherein a gate of the second MOS transistor is electrically connected to the second cable locating control terminal of the first main control circuit; a drain of the second MOS transistor is electrically connected to the signal input terminal of the cable locating signal buffer output circuit and configured to receive the power supply voltage; a source of the second MOS transistor is configured to be grounded.

5. The circuit for implementing cable locating and pairing applied to the cable maintenance equipment according to claim 3, wherein the cable locating signal amplification circuit comprises a second MOS transistor;
wherein a gate of the second MOS transistor is electrically connected to the second cable locating control terminal of the first main control circuit; a drain of the second MOS transistor is electrically connected to the signal input terminal of the cable locating signal buffer output circuit and configured to receive the power supply voltage; a source of the second MOS transistor is configured to be grounded.

6. The circuit for implementing cable locating and pairing applied to the cable maintenance equipment according to claim 2, wherein the cable locating signal buffer output circuit comprises a multi-channel bus buffer;
wherein the multi-channel bus buffer comprises at least a plurality of output enable input pins, a plurality of data input pins, a plurality of data output pins, a power supply pin, and a ground pin;
one of the plurality of output enable input pins is configured as the input/output channel selection terminal of the cable locating signal buffer output circuit; one of the plurality of data input pins is configured as the signal input terminal of the cable locating signal buffer output circuit; one of the plurality of data output pins is configured as the signal output terminal of the cable locating signal buffer output circuit.

7. The circuit for implementing cable locating and pairing applied to the cable maintenance equipment according to claim 3, wherein the cable locating signal buffer output circuit comprises a multi-channel bus buffer;
wherein the multi-channel bus buffer comprises at least a plurality of output enable input pins, a plurality of data input pins, a plurality of data output pins, a power supply pin, and a ground pin;
one of the plurality of output enable input pins is configured as the input/output channel selection terminal of the cable locating signal buffer output circuit; one of the plurality of data input pins is configured as the signal input terminal of the cable locating signal buffer output circuit; one of the plurality of data output pins is configured as the signal output terminal of the cable locating signal buffer output circuit.

8. The circuit for implementing cable locating and pairing applied to the cable maintenance equipment according to claim 6, wherein the multi-channel bus buffer comprises a quad-channel bus buffer, and a model of the quad-channel bus buffer is HC125;
wherein, among the output enable input pin configured as the input/output channel selection terminal of the cable locating signal buffer output circuit, the data input pin configured as the signal input terminal of the cable locating signal buffer output circuit, and the data output pin configured as the signal output terminal of the cable locating signal buffer output circuit, there exists an inter-correspondence relationship.

9. The circuit for implementing cable locating and pairing applied to the cable maintenance equipment according to claim 7, wherein the multi-channel bus buffer comprises a quad-channel bus buffer, and a model of the quad-channel bus buffer is HC125;
wherein, among the output enable input pin configured as the input/output channel selection terminal of the cable locating signal buffer output circuit, the data input pin configured as the signal input terminal of the cable locating signal buffer output circuit, and the data output pin configured as the signal output terminal of the cable locating signal buffer output circuit, there exists an inter-correspondence relationship.

10. The circuit for implementing cable locating and pairing applied to the cable maintenance equipment according to claim 1, wherein the host device further comprises a cable pairing protection circuit;
wherein a first terminal of the cable pairing signal transmission circuit is electrically connected to both a cable pairing control terminal of the first main control circuit and a first terminal of the cable pairing protection circuit, and a second terminal of the cable pairing protection circuit is configured to be grounded.

11. The circuit for implementing cable locating and pairing applied to the cable maintenance equipment according to claim 2, wherein the host device further comprises a cable pairing protection circuit;
wherein a first terminal of the cable pairing signal transmission circuit is electrically connected to both a cable pairing control terminal of the first main control circuit and a first terminal of the cable pairing protection circuit, and a second terminal of the cable pairing protection circuit is configured to be grounded.

12. The circuit for implementing cable locating and pairing applied to the cable maintenance equipment according to claim 3, wherein the host device further comprises a cable pairing protection circuit;
wherein a first terminal of the cable pairing signal transmission circuit is electrically connected to both a cable pairing control terminal of the first main control circuit and a first terminal of the cable pairing protection circuit, and a second terminal of the cable pairing protection circuit is configured to be grounded.

13. The circuit for implementing cable locating and pairing applied to the cable maintenance equipment according to claim 8, wherein the host device further comprises a cable pairing protection circuit;
wherein a first terminal of the cable pairing signal transmission circuit is electrically connected to both a cable pairing control terminal of the first main control circuit and a first terminal of the cable pairing protection circuit, and a second terminal of the cable pairing protection circuit is configured to be grounded.

14. The circuit for implementing cable locating and pairing applied to the cable maintenance equipment according to claim 9, wherein the host device further comprises a cable pairing protection circuit;
wherein a first terminal of the cable pairing signal transmission circuit is electrically connected to both a cable pairing control terminal of the first main control circuit and a first terminal of the cable pairing protection circuit, and a second terminal of the cable pairing protection circuit is configured to be grounded.

15. The circuit for implementing cable locating and pairing applied to the cable maintenance equipment according to claim 10, wherein the cable pairing signal transmission circuit comprises a plurality of cable pairing signal transmission channels, each of the cable pairing signal transmission channels comprises at least a fixed-value resistor and a fuse connected in series; wherein a terminal of the fixed-value resistor is electrically connected respectively to a cable pairing control terminal of the first main control circuit and a first terminal of the cable pairing protection circuit; a terminal of the fuse is electrically connected to a first terminal of the first cable interface;
and/or,
the cable locating signal transmission circuit comprises a plurality of first cable locating signal transmission channels and a plurality of second cable locating signal transmission channels, each of the first cable locating signal transmission channels and the second cable locating signal transmission channels comprises at least one capacitor; wherein a first terminal of each of the first cable locating signal transmission channels is electrically connected to a third terminal of the cable locating signal buffer circuit, and a second terminal of each of the first cable locating signal transmission channels is electrically connected to a first terminal of the first cable interface; a first terminal of each of the second cable locating signal transmission channels is electrically connected to the first terminal of the first cable interface, and a second terminal of each of the second cable locating signal transmission channels is configured to be grounded.

16. The circuit for implementing cable locating and pairing applied to the cable maintenance equipment according to claim 11, wherein the cable pairing signal transmission circuit comprises a plurality of cable pairing signal transmission channels, each of the cable pairing signal transmission channels comprises at least a fixed-value resistor and a fuse connected in series; wherein a terminal of the fixed-value resistor is electrically connected respectively to a cable pairing control terminal of the first main control circuit and a first terminal of the cable pairing protection circuit; a terminal of the fuse is electrically connected to a first terminal of the first cable interface;
and/or,
the cable locating signal transmission circuit comprises a plurality of first cable locating signal transmission channels and a plurality of second cable locating signal transmission channels, each of the first cable locating signal transmission channels and the second cable locating signal transmission channels comprises at least one capacitor; wherein a first terminal of each of the first cable locating signal transmission channels is electrically connected to a third terminal of the cable locating signal buffer circuit, and a second terminal of each of the first cable locating signal transmission channels is electrically connected to a first terminal of the first cable interface; a first terminal of each of the second cable locating signal transmission channels is electrically connected to the first terminal of the first cable interface, and a second terminal of each of the second cable locating signal transmission channels is configured to be grounded.

17. The circuit for implementing cable locating and pairing applied to the cable maintenance equipment according to claim 12, wherein the cable pairing signal transmission circuit comprises a plurality of cable pairing signal transmission channels, each of the cable pairing signal transmission channels comprises at least a fixed-value resistor and a fuse connected in series; wherein a terminal of the fixed-value resistor is electrically connected respectively to a cable pairing control terminal of the first main control circuit and a first terminal of the cable pairing protection circuit; a terminal of the fuse is electrically connected to a first terminal of the first cable interface;
and/or,
the cable locating signal transmission circuit comprises a plurality of first cable locating signal transmission channels and a plurality of second cable locating signal transmission channels, each of the first cable locating signal transmission channels and the second cable locating signal transmission channels comprises at least one capacitor; wherein a first terminal of each of the first cable locating signal transmission channels is electrically connected to a third terminal of the cable locating signal buffer circuit, and a second terminal of each of the first cable locating signal transmission channels is electrically connected to a first terminal of the first cable interface; a first terminal of each of the second cable locating signal transmission channels is electrically connected to the first terminal of the first cable interface, and a second terminal of each of the second cable locating signal transmission channels is configured to be grounded.

18. The circuit for implementing cable locating and pairing applied to the cable maintenance equipment according to claim 15, wherein the slave device further comprises a second main control circuit and a cable locating and pairing signal receiving circuit;
wherein the cable locating and pairing signal receiving circuit comprises a plurality of cable locating and pairing signal receiving channels; a first terminal of each of the plurality of cable locating and pairing signal receiving channels is electrically connected to a first terminal of the second cable interface, a second terminal of each of the plurality of cable locating and pairing signal receiving channels is electrically connected to a cable locating and pairing control terminal of the second main control circuit, and a third terminal of each of the plurality of cable locating and pairing signal receiving channels is configured to be grounded.

19. The circuit for implementing cable locating and pairing applied to the cable maintenance equipment according to claim 16, wherein the slave device further comprises a second main control circuit and a cable locating and pairing signal receiving circuit;
wherein the cable locating and pairing signal receiving circuit comprises a plurality of cable locating and pairing signal receiving channels; a first terminal of each of the plurality of cable locating and pairing signal receiving channels is electrically connected to a first terminal of the second cable interface, a second terminal of each of the plurality of cable locating and pairing signal receiving channels is electrically connected to a cable locating and pairing control terminal of the second main control circuit, and a third terminal of each of the plurality of cable locating and pairing signal receiving channels is configured to be grounded.

20. A cable maintenance equipment, comprising a host device and a slave device, wherein the host device comprises at least a first main control circuit and a first cable interface, the host device further comprises the cable locating and pairing implementation circuit applied to the cable maintenance equipment according to claim 1.
